(19) United States
(12) Patent Application Publication
(10) Pub. No.: US 2023/0148014 A1
(43) Pub. Date: May 11, 2023

(54) INTEGRATED ENERGY HARVESTING SYSTEM

(71) Applicant: Infineon Technologies AG, Neubiberg (DE)

(72) Inventors: Thomas Grille, Nötsch im Gailtal (AT); Elmar Aschauer, Ledenitzen (AT); Ulf Bartl, Villach (AT); Christoph Kovatsch, Finkenstein am Faaker See (AT); Matic Krivec, Villach (AT); Thomas Ostermann, Oberwinklern (AT); Lukas Praster, Kötschach-Mauthen (AT); Gerald Stocker, Goritschach (AT)

(21) Appl. No.: 17/972,910

(22) Filed: Oct. 25, 2022

(30) Foreign Application Priority Data
Nov. 5, 2021 (DE) 102021128880.0

(51) Int. Cl. H02N 2/18; H02N 2/00

(52) U.S. Cl. CPC H02N 2/186; H02N 2/22

(57) ABSTRACT

A MEMS component is described herein, which according to one exemplary embodiment includes: a semiconductor body; an insulation layer arranged on the semiconductor body; a boundary structure arranged on the insulation layer, the semiconductor body including an opening below the boundary structure; first and second structured electrodes arranged on the insulation layer; and a piezoelectric layer comprising a thermoplastic, and at least partially bounded by the boundary structure and arranged on the insulation layer and on the first and second electrodes.

### TECHNICAL FIELD

The present patent application relates to the field of microelectromechanical systems (MEMS), in particular an integrated MEMS for Energy Harvesting.

### BACKGROUND

Energy Harvesting refers to the obtaining of small amounts of electrical energy from sources which are available in the environment, for example ambient temperature, vibrations or air flows. Energy harvesting may, for example, be used to supply autonomous electrical systems or to extend the battery lifetime.

So-called MEMS, which may for example be integrated in silicon substrates, may be used for Energy Harvesting. The Inventors set themselves the object of providing an improved integrated energy harvesting system which, in particular, is straightforward and comparatively inexpensive to produce.

### SUMMARY

A MEMS component is described below, which according to one exemplary embodiment comprises the following: a semiconductor body; an insulation layer arranged on the semiconductor body; a boundary structure arranged on the insulation layer, the semiconductor body comprising an opening below the boundary structure; first and second structured electrodes arranged on the insulation layer; and a piezoelectric layer, comprising a thermoplastic, at least partially bounded by the boundary structure and arranged on the insulation layer and on the first and second electrodes.

A further exemplary embodiment relates to a method for producing a MEMS component. Accordingly, the method comprises providing a semiconductor body; producing an insulation layer on the semiconductor body; producing a material layer on the insulation layer and structuring the material layer to form a boundary structure; producing first and second structured electrodes on the insulation layer; producing a piezoelectric layer comprising a thermoplastic inside the boundary structure on the insulation layer and (at least partially) on the first and second electrodes; and producing an opening in the semiconductor body below the boundary structure.

### BRIEF DESCRIPTION OF THE FIGURES

Various implementations will be explained in more detail below with the aid of the examples which are represented in the figures. The representations are not necessarily true to scale, and the invention is not restricted only to the aspects represented. Rather, the emphasis is placed on representing the underlying principles of the exemplary embodiments represented.

FIG. 1 illustrates a first example of a MEMS component with the aid of a cross-sectional representation.

FIG. 2 is a plan view corresponding to FIG. 1.

FIG. 3 illustrates in diagrams (a) to (d) several parts of a method for producing the MEMS component of FIG. 1.

FIG. 4 illustrates a further example of a MEMS component with the aid of a cross-sectional representation.

FIG. 5 illustrates a further example of a MEMS component with a modified mass element.

### DETAILED DESCRIPTION

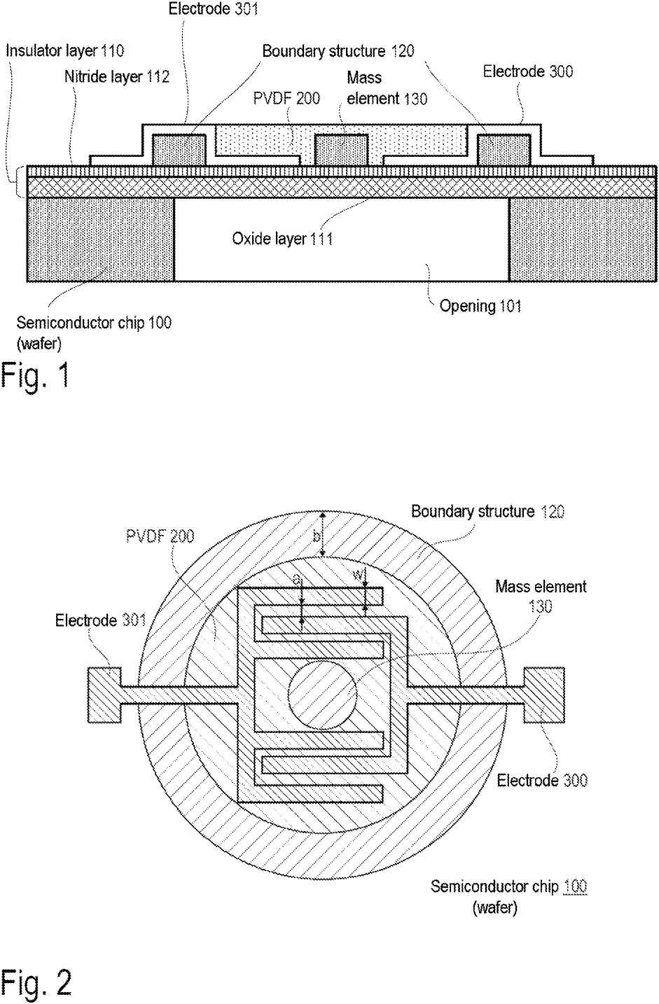

FIG. 1 is a cross-sectional representation of a MEMS component. FIG. 2 is a corresponding plan view. In the example represented, the MEMS component comprises a semiconductor body 100 (for example a silicon substrate) on which an insulation layer 110 is arranged. A boundary structure 120 is arranged on the insulation layer 110, the semiconductor body 100 comprising an opening 101 in the region below the boundary structure 120. In the example represented, that part of the insulation layer 110 which covers the opening 101 forms a membrane capable of oscillation. The MEMS component furthermore comprises first and second structured electrodes 300 and 301 arranged on the insulation layer 110 as well as a piezoelectric layer 200, comprising or consisting of a thermoplastic, at least partially surrounded by the boundary structure 120 and arranged on the insulation layer 110 and at least partially on the electrodes 300, 301. Inside the boundary structure (i.e. surrounded by the latter), a mass element 130 is arranged on the insulation layer. Alternatively (not represented in FIG. 1), the mass element 130 (or optionally a further additional mass element) may be arranged inside the opening 101 (i.e. on the lower side of the insulation layer 110) on the insulation layer 110.

The insulation layer 110 may be produced from a plurality of sublayers so that it has the desired stiffness. In the example represented, the insulation layer 110 comprises an oxide layer 111 (for example silicon oxide) and a nitride layer 112. The oxide layer may, for example, be between 700 and 2300 nm thick. The nitride layer is thinner, and may for example be 60-300 nm thick. The thickness of the silicon substrate may lie in the range of 250-600 µm.

According to the example represented in FIGS. 1 and 2, the mass element 130 and the boundary structure 120 are part of the same structured material layer. Suitable materials are, for example, polycrystalline or amorphous silicon or TEOS (tetraethyl orthosilicate). The boundary structure 120 may form a closed curve (for example a circle as represented in FIG. 2, an oval, a closed polygonal line, etc.) on the upper side of the insulation layer 110. The boundary structure 120 may have a structure width b (see FIG. 2) of less than 30 µm, particularly in the range of 5-30 µm (see FIG. 2), and it partially or fully bounds the piezoelectric layer. The mass element 130 is not necessarily made from the same material as the boundary structure 120. In other exemplary embodiments, the mass element 130 may also be deposited in a separate method step on the insulation layer 110. The mass element 130 may also comprise or consist of metal.

As mentioned, the mass element 130 may alternatively be a (for example isolated) part of the semiconductor body 100 in the interior of the opening. Many exemplary embodiments comprise a plurality of mass elements. That is to say, the two variants (mass element on the upper side and on the lower side of the insulation layer 110) may be combined. In one special exemplary embodiment, no separate mass element 130 is necessary.

The piezoelectric layer comprises PVDF (polyvinylidene fluoride) as a piezoelectric polymer. The piezoelectric layer may comprise or consist of a copolymer which comprises PVDF and TFE (trifluoroethylene).

The electrodes 300, 301 may be part of a structured metallization layer. The first and second electrodes 300, 301 may comprise a multiplicity of stubs arranged interleaved. In other words, the electrodes 300, 301 may comprise a comb-like structure/topology, the “tines” of the comb structures being arranged interleaved. A simplified example is represented in FIG. 2. In the example represented in FIG. 2, the stubs of the electrodes 300, 301 extend substantially parallel to one another with a spacing a and the width of the stubs is denoted by w. The spacing a may for example be 1 µm, and the width w of the conductor tracks is for example 6 µm. It is to be understood that the numerical values are merely illustrative examples and that these numerical values may also be different in various exemplary embodiments.

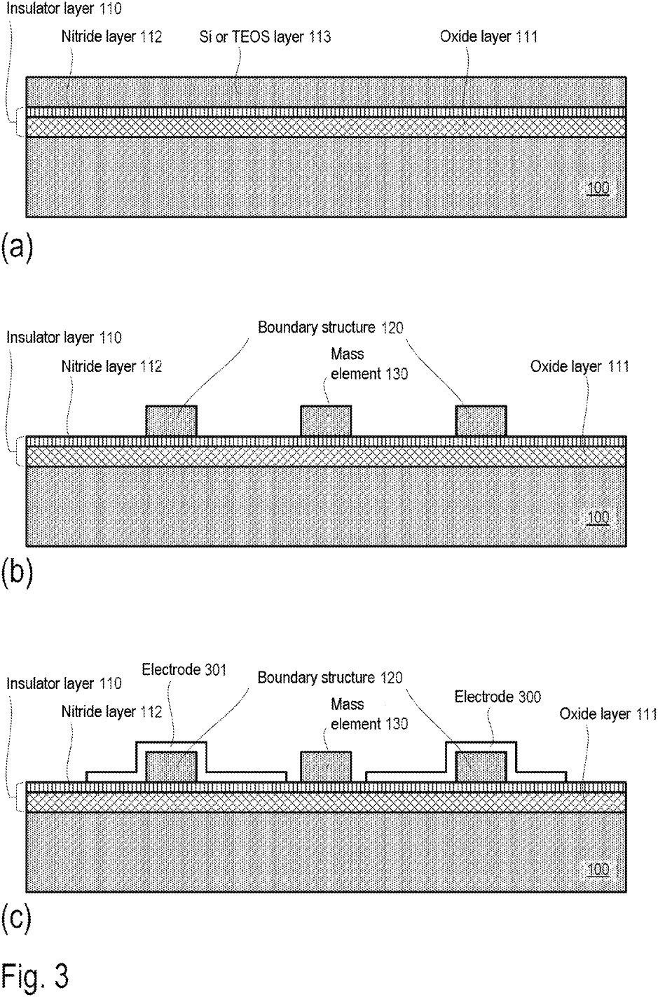

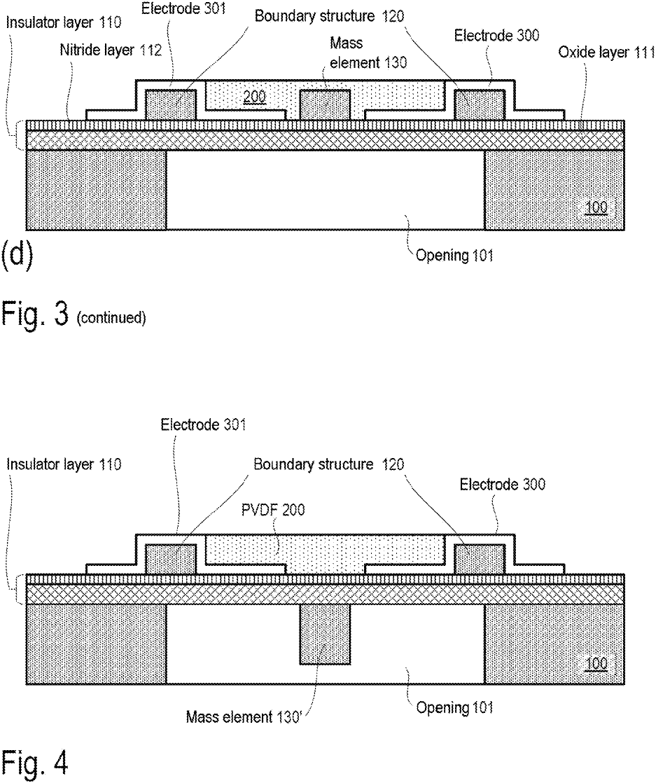

One possible production method, by which the MEMS component of FIG. 1 may be produced, will be described below by way of example. Diagrams (a) to (d) of FIG. 3 show various intermediate states of the product in the course of the method.

In a first part of the method, an insulation layer 110 is produced on a semiconductor body 100 (for example a silicon wafer), and a material layer is subsequently deposited on this insulation layer 110. Various possibilities for the production of an insulation layer on a semiconductor substrate are known. In the example represented, an oxide layer 111 is produced on the surface of the silicon wafer and a nitride layer 112 is produced thereon. The insulation layer 110 may thus comprise or consist of a plurality of different coats. The material layer 113 arranged on the insulation layer 110 may, for example, be a layer of polycrystalline or amorphous silicon. In many exemplary embodiments, the material layer 113 comprises or consists of TEOS, in particular PETEOS (plasma enhanced TEOS), which is deposited by means of a CVD process (CVD = Chemical Vapor Deposition). The result of this part of the method is represented in diagram (a) of FIG. 3.

By structuring the material layer 113 (for example by means of photolithography and etching), a boundary structure 120 and - optionally - a mass element 130 are produced on the upper side of the insulation layer 110. The boundary structure 120 may, as mentioned, have the shape of a closed curve, for example a circle (see FIG. 2), an oval, or a closed polygonal line. The boundary structure 120 need not necessarily form a closed curve, however, but may also comprise interruptions. Diagram (b) shows the result of this part of the method, after the boundary structure 120 and the mass element 130 has been produced from the material layer 113, the mass element 130 being surrounded by the boundary structure 120.

In the next step, first and second structured electrodes 300, 301 are produced on the insulation layer 110 (for example from aluminum or copper). The electrodes 300, 301 may also extend beyond the boundary structure 120. Techniques for the production of structured electrodes on a semiconductor wafer are known per se and will not be further discussed here. The comb-like interleaved structure of the electrodes 300, 301 has been explained above with reference to FIG. 2. The result of this part of the method is represented in diagram (c) of FIG. 3. The lower side (often referred to as the backside) of the wafer may subsequently be ground until the semiconductor body has the desired thickness of 250-600 µm (for example 400 µm). The grinding, or thinning, of the wafer is a standard process and is not explicitly represented.

Before or after the grinding/thinning of the wafer, a piezoelectric layer 200 comprising or consisting of a thermoplastic is produced on the insulation layer 110 and on the electrodes 300, 301 and inside the boundary structure 120. Furthermore, an opening 101 is produced (for example by means of photolithography and etching) in the semiconductor body 100 below the boundary structure 120. The result is represented in diagram (d) of FIG. 3. The production of the opening in the example represented produces a membrane capable of oscillation, which substantially comprises the insulation layer 110 and the mass element 130. At this point, it should be emphasized that the geometrical shape of the mass element 130 need not necessarily be round. The mass element 130 may have any desired shape with which the desired effect is achieved, namely adaptation/adjustment of the mechanical properties of the membrane, i.e. the oscillation modes and the associated natural frequencies of the membrane. Furthermore, the mechanical properties of the membrane may also be influenced by the number of coats (sublayers) of the insulation layer 110 and the material used therefor. In many exemplary embodiments, materials other than the aforementioned oxide and nitride may also be used.

It is to be understood that the ordering of the method steps need not necessarily be carried out in the order described. Depending on the semiconductor technology used, for example, the piezoelectric layer 200 may be produced before or after the production of the opening 101. Furthermore, it is to be understood that only the steps necessary or helpful for understanding of the exemplary embodiments are discussed here, and other steps (known per se) which may be necessary for the production of an integrated circuit are omitted. After the production of the MEMS components on a wafer, the latter may be divided into individual chips, which may subsequently be packaged in suitable chip housings.

FIG. 4 shows a further exemplary embodiment, which may be regarded as an alternative to the example of FIG. 1. In this example, the mass element was not produced on the upper side of the insulation layer 110 from the same material layer as the boundary structure 120, but instead a mass element 130′ was produced on the lower side of the insulation layer 110. For example, by means of a multistage etching process, the production of the opening 101 may be configured in such a way that a piece of silicon remains as a mass element 130′ in the opening 101. The mass element 130 may be isolated from the semiconductor body 100. In many exemplary embodiments, two or more mass elements 130, 130′ may be produced on both sides of the insulation layer 110 (that is to say a combination of the examples of FIGS. 1 and 4).

As mentioned, that part of the insulation layer 110 which covers the opening 101 forms a membrane capable of oscillation. The size of the mass element 130 (and/or 130′) has an influence on the oscillation modes and the natural frequency of the membrane. As already mentioned, by a suitable design of the mass element in relation to size and shape, the mechanical properties of the membrane, in particular the oscillation modes and the associated natural frequencies of the membrane, may (within certain limits) be adjusted and adapted to the application.

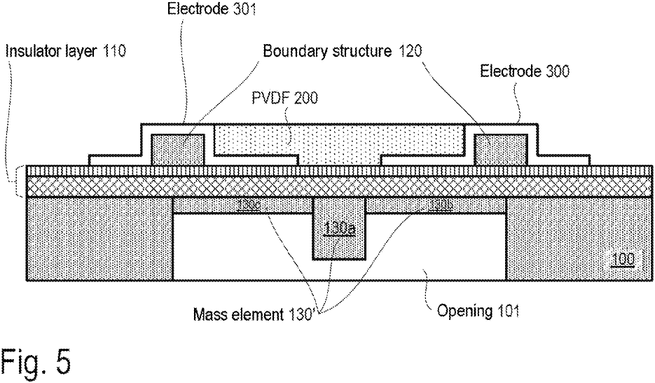

The mass element 130′ need not necessarily be fully separated from the semiconductor body 100. FIG. 5 illustrates a modification of the example of FIG. 4, in which a central part 130a of the mass element 130′ is connected via a plurality of struts 130b, 130c to the surrounding semiconductor body. The struts 130b, 130c may, for example, extend in the radial direction from the part 130a to the edge of the opening 101. The struts 130b, 130c may also form a network structure or grid structure. The thickness of the struts influences the thickness and the stability of the membrane.

A mechanical movement of the MEMS component leads to oscillation of the membrane and, because of the piezoelectric effect, to a voltage between the electrodes 300, 301, or to a corresponding displacement of electrical charges. The resulting electrical energy may be used in a manner known per se to charge an energy storage unit (capacitor or battery) or to power an electronic circuit.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A MEMS component, comprising:
a semiconductor body;
an insulation layer arranged on the semiconductor body;
a boundary structure arranged on the insulation layer, the semiconductor body comprising an opening below the boundary structure;
first and second structured electrodes arranged on the insulation layer; and
a piezoelectric layer comprising a thermoplastic, the piezoelectric layer at least partially bounded by the boundary structure and arranged on the insulation layer and on the first and second electrodes.

2. The MEMS component of claim 1, further comprising:
a mass element,
wherein the mass element is arranged on the insulation layer inside the boundary structure or is arranged on the insulation layer inside the opening.

3. The MEMS component of claim 2, wherein the mass element and the boundary structure are parts of a same structured material layer.

4. The MEMS component of claim 2, wherein the mass element is formed in an interior of the opening from a part of the semiconductor body.

5. The MEMS component of claim 2, wherein the mass element is enclosed by the boundary structure.

6. The MEMS component of claim 1, wherein the boundary structure forms a closed curve.

7. The MEMS component of claim 1, wherein the insulation layer comprises an oxide layer and a nitride layer.

8. The MEMS component of claim 7, wherein the oxide layer is arranged on the semiconductor body and the nitride layer is arranged on the oxide layer.

9. The MEMS component of claim 1, wherein the thermoplastic comprises polyvinylidene fluoride.

10. The MEMS component of claim 9, wherein the thermoplastic is a copolymer of polyvinylidene fluoride and trifluoroethylene.

11. The MEMS component of claim 1, wherein the boundary structure bounds the piezoelectric layer.

12. The MEMS component of claim 1, wherein the boundary structure is a structured layer of silicon.

13. The MEMS component of claim 1, wherein the boundary structure is a structured layer of tetraethyl orthosilicate.

14. A method, comprising:
providing a semiconductor body;
producing an insulation layer on the semiconductor body;
producing a material layer on the insulation layer and structuring the material layer to form a boundary structure;
producing first and second structured electrodes on the insulation layer;
producing a piezoelectric layer comprising a thermoplastic inside the boundary structure on the insulation layer and on the first and second electrodes; and
producing an opening in the semiconductor body below the boundary structure.

15. The method of claim 14, further comprising:
producing a mass element on the insulation layer inside the boundary structure.

16. The method of claim 15, wherein the mass element is a part of the structured material layer.

17. The method of claim 15, wherein the mass element is an isolated part of the semiconductor body.

18. The method of claim 14, further comprising:
producing a mass element on the insulation layer inside the opening.

19. The method of claim 18, wherein the mass element is a part of the structured material layer.

20. The method of claim 18, wherein the mass element is an isolated part of the semiconductor body.
